(19) United States
(12) Patent Application Publication
(10) Pub. No.: US 2006/0054927 A1
(43) Pub. Date: Mar. 16, 2006

(54) Sensor using a GaN transistor

(75) Inventors: Wen-Kai Wang, Jhongli City (TW); Jin-Wei Shi, Taipei (TW); Yi-Jen Chan, Jhongli City (TW)

Correspondence Address: TROXELL LAW OFFICE PLLC, SUITE 1404, 5205 LEESBURG PIKE, FALLS CHURCH, VA, 22041, US

(73) Assignee: National Central University

(21) Appl. No.: 11/143,861

(22) Filed: Jun. 3, 2005

(30) Foreign Application Priority Data
Sep. 10, 2004 (TW) 093127354

(51) Int. Cl. H01L 31/0328

(52) U.S. Cl. 257/194

(57) ABSTRACT

The present invention uses a GaN transistor grown over a Si substrate, which is obtained by etching through lithography or a plasma etching; and is used as a pressure sensor with great sensitivity by utilizing the characteristic of piezoelectric effect of GaN with the ability of magnifying signals and providing very high sensitivity; and is integrated into an IC, or into a micro electro-mechanical system of Si semiconductor.

### FIELD OF THE INVENTION

The present invention relates to a sensor; more particularly, relates to etching the part of a Si substrate at the back of a GaN transistor through a plasma etching to form a thin-film GaN transistor to be a pressure sensor having the greatest capability of environmental

### DESCRIPTION OF THE RELATED ART(S)

A prior art is described in a patent of U.S. Pat. No. 6,579,068 B2 “Method of Manufacture of a Suspended Nitride Membrane and a Microperistaltic Pump Using the Same”. As shown in FIG. 5, epitaxies 51,52 of p-GaN and n-GaN are grown on a sapphire layer 53 of a thin-film GaN pressure sensor. By utilizing a highly-selective wet etching formed with the cooperation of UV and potassium for easily etching a n-GaN and hardly etching a p-GaN, a thin-film GaN pressure sensor is obtained while p-GaN is left. Yet, the procedure is complex; and, because the thin-film p-GaN is a passive device, its sensitivity is lower. So, the prior art does not fulfill users' requests on actual use.

### SUMMARY OF THE INVENTION

Therefore, the main purpose of the present invention is to provide a sensor using a GaN transistor, which has the advantages of a very high sensitivity, a function of magnifying signals, and a greatest capability of environmental tolerance.

To achieve the above purpose, the present invention is a sensor using a GaN transistor, comprising a hollow Si substrate with a nucleation layer, a buffer layer and a Schottky layer grown as epitaxies over the hollow Si substrate And, a source and a drain a regrown as epitaxies at two opposite ends over the Schottky layer, and a gate is formed between the source and the drain. Hence, a sensor using a GaN transistor is obtained, which is structured as a HEMT (High Electron Mobility Transistor).

In another way, the present invention provides a sensor using a GaN transistor, comprising a hollow Si substrate with a nucleation layer, a buffer layer, a channel and a cap layer grown as epitaxies over the hollow Si substrate. And, a source and a drain are grown as epitaxies at two opposite ends over the cap layer, and a gate is formed between the source and the drain. Hence, a sensor using a GaN transistor is obtained, which is structured as a MESFET (Metal Semiconductor Field Effect Transistor).

The present invention is a sensor using a GaN transistor grown over a Si substrate, which is obtained by etching the part of the Si substrate at the back of the GaN transistor through a lithography or a plasma etching. The present invention can be used as a pressure sensor with great sensitivity by utilizing the characteristic of piezoelectric effect of GaN with the ability of magnifying signals and of providing a very high sensitivity. And, the present invention can be integrated into an IC, or a micro electromechanical system of Si semiconductor, etc.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is a view of a first embodiment according to the present invention;

FIG. 2 is a view of a second embodiment according to the present invention;

FIG. 3A to FIG. 3C are views of the manufacture steps for a hollow Si substrate of the first embodiment according to the present invention; and

FIG. 4A to FIG. 4C are views of the manufacture steps for a hollow Si substrate of the second embodiment according to the present invention; and

FIG. 5 is a view of a thin-film pressure sensor made of p-GaN and n-GaN according to a prior art.

### DESCRIPTION OF THE PREFERRED EMBODIMENTS

The following descriptions of the preferred embodiments are provided to understand the features and the structures of the present invention.

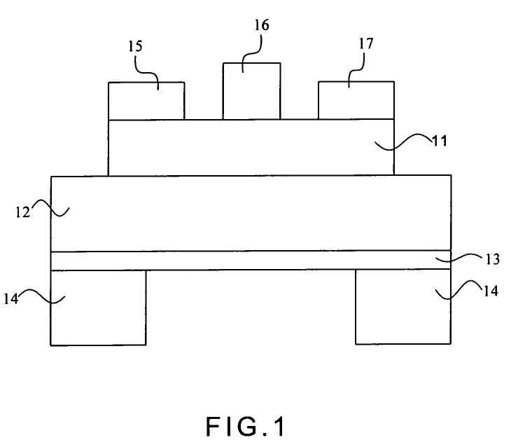

Please refer to FIG. 1, which is a view of a first embodiment according to the present invention. As shown in the figure, the first embodiment provides a sensor using a GaN transistor, comprising a hollow Si substrate 14, a nucleation layer 13, a buffer layer 12 and a Schottky layer 11, wherein the epitaxies of the nucleation layer 13, the buffer layer 12 and the Schottky layer 11 are grown over the hollow Si substrate 14; and wherein epitaxies of a source 15 and a drain 16 are grown at the opposite ends on the Schottky layer 11, and a gate 17 is formed between the source 15 and the drain 16. Hence, the first embodiment of a sensor using a GaN transistor is obtained, which is structured as a HEMT (High Electron Mobility Transistor). The structure of the first embodiment according to the present invention is simple, which only requires epitaxies of a nucleation layer, a buffer layer and a Schottky layer grown on a Si substrate. And the materials used in the first embodiment are as follow: AlGaN for the Schottky layer 11, GaN for the buffer layer 12 and AlN for the nucleation layer 13.

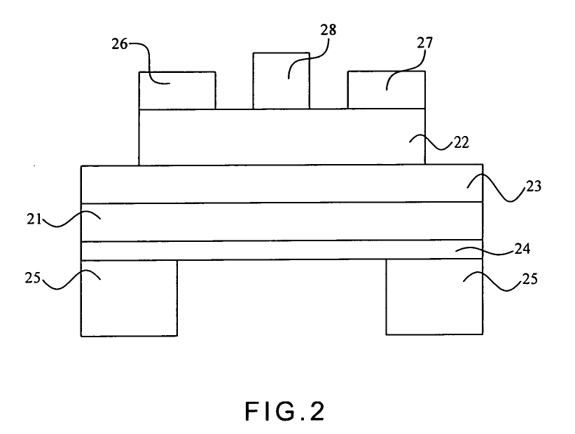

Please refer to FIG. 2, which is a view of a second embodiment according to the present invention. As shown in the figure, the second embodiment provides a sensor using a GaN transistor, comprising a hollow Si substrate 25, a nucleation layer 24, a buffer layer 23, a channel 22 and a cap layer 21, wherein the epitaxies of the nucleation layer 24, the buffer layer 23, the channel 22 and the cap layer 21 are grown over the hollow Si substrate 25; and wherein epitaxies of a source 26 and a drain 27 are grown at two opposite ends on the cap layer 21, and a gate 28 is formed between the source 26 and the drain 27. Hence, the second embodiment of a sensor using a GaN transistor is obtained, which is structured as a MESFET (Metal Semiconductor Field Effect Transistor). The structure of the second embodiment according to the present invention is simple, which only requires epitaxies of a nucleation layer, a buffer layer, a channel and a cap layer grown on a Si substrate. And the materials used in the second embodiment are as follow: GaN for the cap layer 21, n-GaN for the channel 22, GaN for the buffer layer 23 and AlN for the nucleation layer 24.

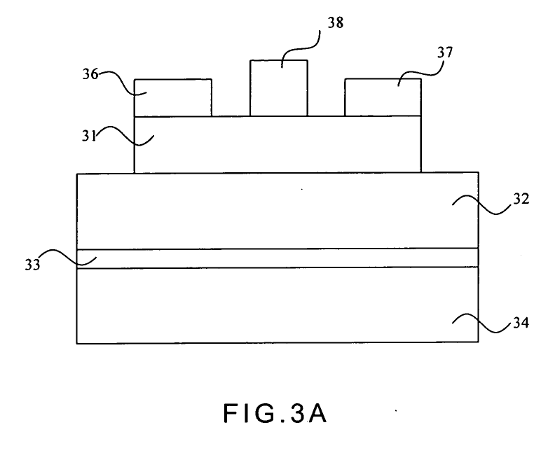

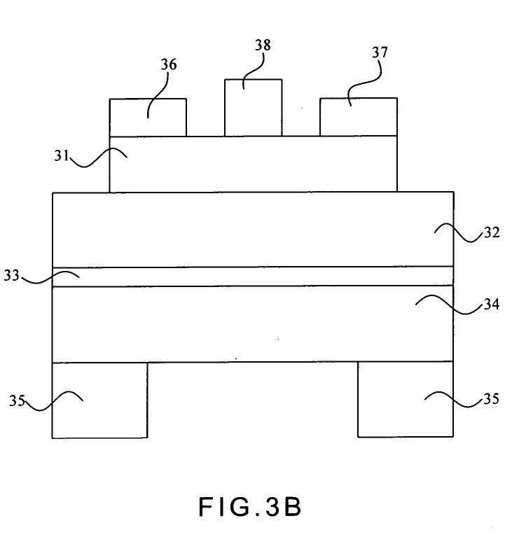

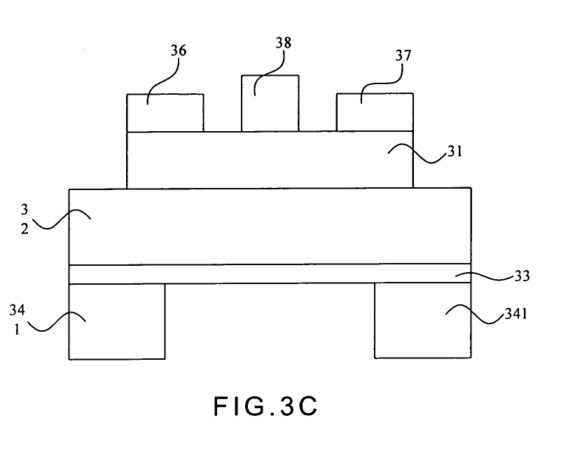

Please refer to FIG. 3A through FIG. 3C, which are views of the manufacture steps for a hollow Si substrate of the first embodiment according to the present invention. As shown in the figures, the first embodiment according to the present invention comprises a hollow Si substrate 341, a nucleation layer 33, a buffer layer 32 and a Schottky layer 31, where epitaxies of a source 36 and a drain 37 are grown at two opposite ends on the Schottky layer 31 and a gate 38 is formed between the source 36 and the drain 37. Herein, the manufacture steps for the hollow Si substrate 341 include: (a) Obtaining a GaN transistor structured as a HEMT, which is made of a base material of the Si substrate 34 and comprises at least the Si substrate 34, the nucleation layer 33, the buffer layer 32 and the Schottky layer 31 (please refer to FIG. 3A); and (b) Proceeding a backside process of plasma etching by lithography or a dry etching to scoop out Si substrate 34, or proceeding a backside process of plasma etching by applying a dry etching somewhere on the Si substrate 34 according to the requirement (please refer to FIG. 3B). Hence, the hollow Si substrate 341 is formed to obtain a thin-film GaN transistor of the first embodiment (please refer to FIG. 3C).

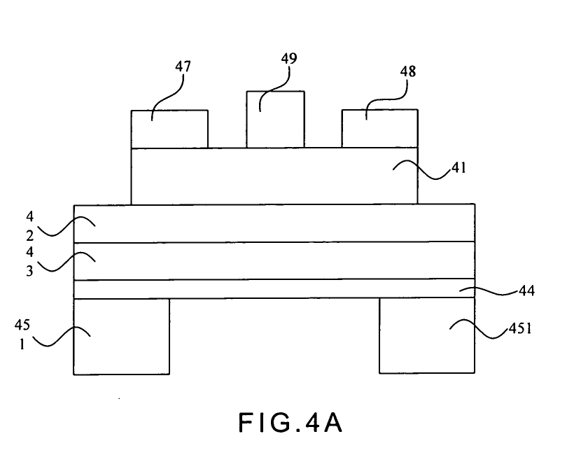

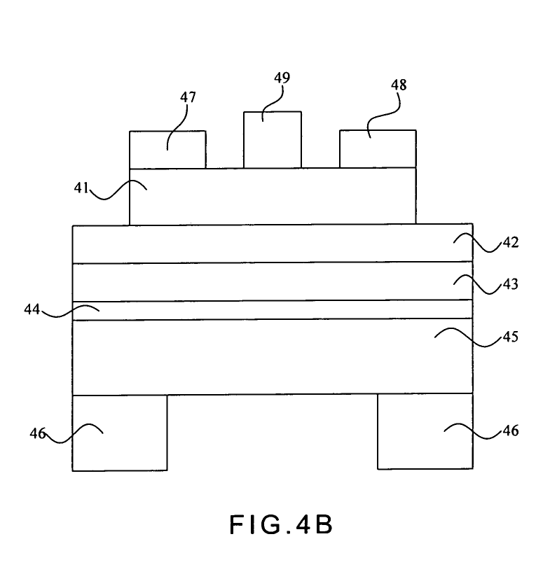

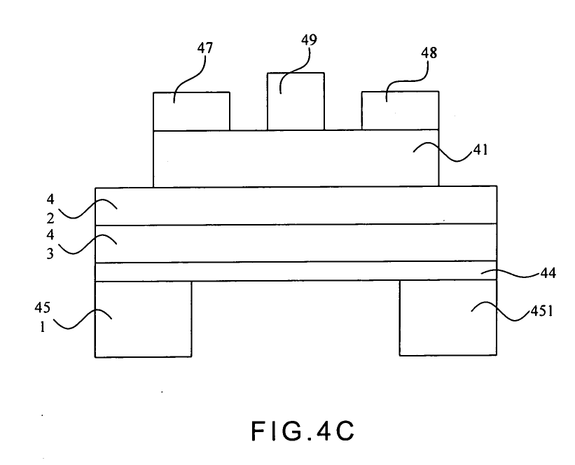

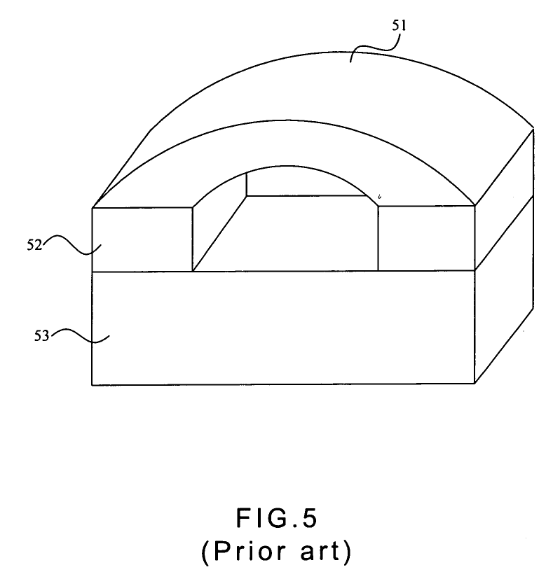

Please refer to FIG. 4A through FIG. 4C, which are views of the manufacture steps for a hollow Si substrate of the second embodiment according to the present invention. As shown in the figures, the second embodiment according to the present invention comprises a hollow Si substrate 451, a nucleation layer 44, a buffer layer 43, a channel 42 and a cap layer 41, where epitaxies of a source 47 and a drain 48 are grown at two opposite ends on the cap layer 41 and a gate 49 is formed between the source 47 and the drain 48. Herein, the manufacture steps for the hollow Si substrate 451 include: (a) Obtaining a GaN transistor structured as a MESFET, which is made of a base material of the Si substrate 45 and comprises at least the Si substrate 45, the nucleation layer 44, the buffer layer 43, the channel 42 and the cap layer 41 (please refer to FIG. 4A); and (b) Proceeding a backside process of plasma etching by lithography or a dry etching to scoop out Si substrate 45, or proceeding a backside process of plasma etching by applying a dry etching somewhere on the Si substrate 45 according to the requirement (please refer to FIG. 4B) Hence, the hollow Si substrate 451 is formed to obtain a thin-film GaN transistor of the second embodiment (please refer to FIG. 4C).

The above manufacture steps for the hollow Si substrate 341,451 exclude some complex processes, such as making a floating arm, etc., so that the manufacture procedure is simple and good characteristics can be obtained, where the present invention can be used as a pressure sensor. And, the pressure sensor is an active device, which uses the gate 38,49 to accept signals of pressure changes and magnifies the signals by the function of the active device. Therefore, the present invention can magnifies the signals of pressure changes; can obtain a pressure sensor with great sensitivity by utilizing the characteristic of piezolelectric effect of the GaN; and can be used in rigorous environments because of the greatest capability of tolerance owing to the widest bandgap of GaN, such as used in a furnace of a high temperature environment application or in a space exploring. Besides, the pressure sensor, being an active device, can be integrated into an integrated circuit (IC), such as being integrated with an amplifier to improve its sensitivity; or, can be integrated into a micro electro-mechanical system, such as being integrated with an arm device to obtained a single-crystal integrated apparatus.

Accordingly, the present invention is a sensor using a GaN transistor grown over a Si substrate, which is obtained by etching the part of the Si substrate at the back of the GaN transistor through lithography or a plasma etching to form a thin-film GaN transistor. The manufacture steps according to the present invention are simple because of excluding some complex processes like making a floating arm. The present invention can be used as a pressure sensor with great sensitivity by utilizing the characteristic of piezo electric effect of GaN with the ability of magnifying signals and providing a very high sensitivity. And, the present invention can be integrated into an IC, or a micro electro-mechanical system of Si semiconductor, etc.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A sensor using a GaN transistor, comprising:
a hollow Si substrate;
a nucleation layer deposed over said Si substrate;
a buffer layer deposed over said nucleation layer;
a Schottky layer deposed over said buffer layer;
a source and a drain deposed at two opposite ends over said Schottky layer; and
a gate deposed between said source and said drain over said Schottky layer.

2. The sensor according to claim 1, wherein said sensor using a GaN transistor is a High Electron Mobility Transistor.

3. The sensor according to claim 1, wherein a structure of said buffer layer and said Schottky layer is an epitaxy over said Si substrate.

4. The sensor according to claim 1 wherein manufacturing said hollow Si substrate comprises:
(a) Obtaining a GaN transistor over a Si substrate; and
(b) Scooping out at the back of said Si substrate by a plasma etching to obtain said hollow Si substrate.

5. The sensor according to claim 4, wherein said plasma etching is a dry etching.

6. The sensor according to claim 4, wherein said plasma etching is a process of lithography.

7. The sensor according to claim 1, wherein said GaN transistor is a pressure sensor.

8. The sensor according to claim 7, wherein said pressure sensor is an active device.

9. The sensor according to claim 7, wherein said pressure sensor comprises a characteristic of GaN piezoelectric effect.

10. The sensor according to claim 7, wherein said pressure sensor comprises broadest band gap of GaN.

11. The sensor according to claim 7, wherein said pressure sensor is an integrated circuit.

12. A sensor using a GaN transistor comprising:
a hollow Si substrate;
a nucleation layer deposed over said Si substrate;
a buffer layer deposed over said nucleation layer;
a channel deposed over said buffer layer;
a cap layer deposed over said channel;
a source and a drain deposed at two opposite ends over said Schottky layer; and
a gate deposed between said source and said drain over said Schottky layer.

13. The sensor according to claim 12 wherein said sensor using a GaN transistor is a Metal Semiconductor Field Effect Transistor.

14. The sensor according to claim 12 wherein a structure of said buffer layer and said cap layer is an epitaxy over said Si substrate.

15. The sensor according to claim 12, wherein manufacturing said hollow Si substrate comprises:
(a) Obtaining a GaN transistor over a Si substrate; and
(b) Scooping out at the back of said Si substrate by a plasma etching to obtain said hollow Si substrate.

16. The sensor according to claim 15, wherein said plasma etching is a dry etching.

17. The sensor according to claim 15, wherein said plasma etching is a process of lithography.

18. The sensor according to claim 12, wherein said GaN transistor is a pressure sensor.

19. The sensor according to claim 18, wherein said pressure sensor is an active device.

20. The sensor according to claim 18, wherein said pressure sensor comprises a characteristic of GaN piezolelectric effect.

21. The sensor according to claim 18, wherein said pressure sensor comprises broadest bandgap of GaN.

22. The sensor according to claim 18, wherein said pressure sensor is an integrated circuit.
